(19) United States
(12) Patent Application Publication
(10) Pub. No.: US 2008/0054260 A1
(43) Pub. Date: Mar. 6, 2008

(54) Semiconductor Integrated Circuit Device, Method For Testing The Semiconductor Integrated Circuit Device, Semiconductor Wafer And Burn-In Test Apparatus

(76) Inventors: Takashi Ishitobi, Osaka (JP); Takashi Ohtori, Osaka (JP); Yasushi Tanaka, Osaka (JP)

Correspondence Address: MCDERMOTT WILL & EMERY LLP, 600 13TH STREET, NW, WASHINGTON, DC, 20005-3096, US

(21) Appl. No.: 11/661,680

(22) PCT Filed: Jun. 1, 2005
(86) PCT No.: PCT/JP05/10072

§ 371 Date: Mar. 2, 2007

(30) Foreign Application Priority Data
Sep. 2, 2004 (JP) 2004-255411
Mar. 2, 2005 (JP) 2005-057831

(51) Int. Cl. H01L 23/58; G01R 31/02; G06F 19/00

(52) U.S. Cl. 257/48; 324/763; 700/110; 257/E23.194

(57) ABSTRACT

A wafer test is performed to a wafer, and then a protective film is applied to part of a chip surface of each good chip other than terminals. For defective chips, a protective film is applied to an entire chip surface as well as terminals and, while keeping that state, a burn-in test is performed, thereby cutting off power supply and signal application to defective chips before burn-in test. Moreover, when a chip includes a self-test circuit to judge whether the chip is good or not and the chip is judged to be defective, the function of stopping an internal operation of the chip may be provided or a judgment signal may be transmitted to a burn-in test apparatus, thereby stopping power supply and signal application from the burn-in test apparatus. Thus, power supply and signal application to a chip judged to be defective after burn-in can be cut off.

### TECHNICAL FIELD

The present invention relates to a burn-in test method in which burn-in or a test can be performed to a plurality of semiconductor integrated circuit devices at a time and a semiconductor integrated circuit device used in the burn-in test method.

### BACKGROUND ART

In recent years, there has been remarkable progress in reduction in size and price of electric equipment in which a semiconductor integrated circuit device is mounted. Accordingly, demands for reduction in size and price of semiconductor integrated circuit devices are increased.

In the mean time, as the degree of integration and function of semiconductor integrated circuits have been improved, test steps for testing a semiconductor integrated circuit device (which will be hereafter referred to a “chip”) have become complicated, thus resulting in increase in test costs. Furthermore, there are increased needs for eliminating initial failure using burn-in. Also, increase in time required for burn-in leads to increase in test costs.

A burn-in test is usually performed to a plurality of chip regions (which will be herein merely referred to as a “chip”) formed in a single board (device) at a time. As a condition for effectively performing a burn-in test, mixture of a defective chip has to be avoided in burn-in steps. If a defective chip is mixed in, a flow of a large current in the defective chip might be caused due to short circuit of an interconnect, latch-up phenomenon or the like and a voltage drop occurs. This might prevent a normal burn-in test to good chips on the same board (device). Also, this might leads cases where a good chip is broken or, in the worst case, a test apparatus itself is broken. As described above, mixture of a defective chip might lead unnecessary increase in test costs. Therefore, it is very important to prevent mixture of a defective chip in burn-in steps.

There are two types of defective chips which can be possibly mixed in burn-in steps. Those are a defective chip which has been defective before burn-in steps are started and a defective chip which is generated while burn-in steps are performed.

First, a defective chip which has been defective before burn-in steps is normally screened by a test. Especitally, in the case of wafer level burn-in, all chips formed in a wafer are tested, whether each of the chips is good or not is judged, and then a defective chip is removed. As a method for removing a defective chip, as disclosed in Japanese Laid-Open Publication No. 7-169806 (Patent Reference 1), a power source of a defective chip and an electrode portion of a signal line terminal of the defective chip are covered with a nonconducting resin film, thereby cutting off power supply to the defective chip.

FIG. 11 is a flowchart showing a known method for testing a semiconductor integrated circuit. As shown in FIG. 11, after completion of semiconductor diffusion process, in order to perform screening for a defective chip, all chips formed in a wafer is tested in a wafer state. As test contents, short circuit between a power source and a GND, a simple operation test and the like may be performed. Alternatively, when a self-test circuit is provided in a chip and burn-in is performed using the self-test circuit, a test of the self-test circuit, a function test using a DC and an AC, and the like may be performed. A chip which has been judged to be defective in a test is marked, so that a good chip can be separated from a defective chip. Next, a defective chip is removed according to the marking. A method for removing a defective chip is that a power source of a defective chip and an electrode portion of a signal line terminal of the defective chip are covered with a nonconducting resin film, thereby cutting off power supply to the defective chip. Then, burn-in is performed.

Next, a method for removing influences of a defective chip generated when burn-in is performed will be described. Even if a chip is judged to be good before a burn-in test, the chip might be judged to be defective by a burn-in test. In such a case, the chip gives adverse influences to good chips in the same manner as a chip judged defective by a test before a burn-in test. To cope with this problem, as disclosed in Japanese Laid-Open Publication No. 8-170977 (Patent Reference 2), a current limiting circuit is provided in each chip to limit current supply when a defective chip is generated and a current at an amount exceeding a predetermined level. According to the method, a burn-in test can be accurately performed and breakdown of a test apparatus can be avoided.
Patent Reference 1 Japanese Laid-Open Publication No. 7-169806
Patent Reference 2 Japanese Laid-Open Publication No. 8-170977

### DISCLOSURE OF THE INVENTION

Problems that the Invention is to Solve

However, with the known method described in Patent Reference 1, a power supply source of a defective chip and an electrode portion of a signal line of the defective chip have to be reliably covered with a nonconducting resin film. If burn-in is performed with incomplete resin coating, a flow of a large current in a defective chip is caused and the defective chip gives adverse influences to a good chip.

In the known method described in Patent Reference 2, a current limiting circuit is provided in each chip, thereby limiting current supply to a defective chip in which a current at an amount exceeding a predetermined level. However, an operation of the defective chip itself can not be stopped, so that unnecessary power is still supplied.

Moreover, in a known burn-in test, there is no recoding mechanism for recording how many defective chips are generated after how many hours from a start of the test. Accordingly, a convergence of initial failure occurrence in burn-in test steps can not be accurately understood. Therefore, it takes some time to set an appropriate burn-in time.

When a burn-in test is performed to chips in a wafer state, a limit is imposed on the number of terminals which can be used because of physical restrictions of a probe card. As the number of chips obtained from a signal wafer is increased due to reduction in size of semiconductor diffusion process design and increase in diameter of a wafer, the number of terminals (contacts) of probes which can be used per chip is reduced, so that a power supply shortage and an applied signal supply shortage are caused. This adversely affects a test.

A time for performing a burn-in test is normally several hours to several days. This has been a large factor of test costs and leads to increase in an all-over test costs.

The present invention has been devised to solve at least one of the above-described problems. It is therefore an object of the present invention to provide a test method which allows an accurate burn-in test and reduction in needless power at a test and a semiconductor integrated circuit used in the test method.

Solution to the Problems

As means to solve the above-described problems, the flow of the known semiconductor diffusion process and the flow of the known wafer level burn-in are changed. In the impurity diffusion process, diffusion is temporarily stopped before the step of adding an insulating surface protective film to a wafer, a wafer test is performed to the wafer before adding insulating surface protective film and coordinates of good chips or defective chips are extracted. After the wafer test, based on the extracted coordinates, a normal protective film mask, i.e., a protective film for protecting part of a chip surface other than terminals is formed on the good chips and a protective film mask covering an entire chip is formed on the defective chips. Thus, terminals of the defective chips are made nonconductive by the insulating surface protective film while a burn-in test is performed, so that power supply and signal application to the defective chips are cut off.

Moreover, as another means to solve the above-described problems, a self-test circuit is provided in a chip to judge whether or not the chip is good. Alternatively, an off-chip circuit having the same function as the self-test circuit is provided. As the function of the self-test circuit, when a tested chip is judged to be defective, the self-test circuit stops or fixes a clock signal in a chip. Unnecessary power supply can be reduced by stopping an operation of a defective chip. Moreover, a judgment signal is transmitted to a burn-in test apparatus and power supply and signal application from the burn-in test apparatus are stopped and power supply and signal application to the defective chip are cut off.

Moreover, as another means to solve the above-described problems, a judgment signal output from a self-test circuit of a chip is transmitted to the burn-in test apparatus. The function of recording, when the apparatus receives a FAIL judgment signal, at what time and how many times the burn-in test apparatus has received the FAIL signal may be provided.

Moreover, as another means to solve the above-described problems, for example, interconnects are formed along scribe lines on a wafer so that an output signal of a chip can be applied as an input signal to an input terminal of another chip. Thus, an input application signal can be supplied from an output signal of another chip, so that a signal can be applied to many chips with a small number of probe terminals.

Moreover, as another means to solve the above-described problems, using a self-test circuit provided in or outside a chip, a probe test and a test similar to a shipping test are performed. Thus, a known probe test and a known shipping test can be eliminated, so that reduction in test const can be reduced.

Therefore, a first method for testing a semiconductor integrated circuit device according to the present invention includes the steps of: a) testing whether a semiconductor chip formed in a wafer is good or not in a wafer state, the semiconductor chip including an integrated circuit having an electrode pad; b) forming a first insulating protective film on part of the semiconductor chip other than the electrode pad when it has been judged as to be good in the step a); c) forming a second insulating protective film on an entire upper surface of the semiconductor chip when it has been judged to be defective in the step a); and d) performing a burn-in test of the wafer using a burn-in test apparatus.

According to this embodiment, in a burn-in test, power supply and signal application to a defective chip can be reliably cut off, so that a flow of a large current having a current value equal to or larger than a predetermined value in a good chip can be prevented.

A second test method for testing a semiconductor integrated circuit device according to the present invention is a method for testing a semiconductor integrated circuit device, in which a burn-in test of an integrated circuit provided on a semiconductor chip formed in a wafer and including a self-test circuit is performed using a burn-in test apparatus and a probe card in which a probe terminal is provided and which is to be connected to the burn-in test apparatus when a test is performed. The method includes the step of a) performing a burn-in test of electric characteristics of the integrated circuit in a wafer level by connecting an input terminal on the semiconductor chip and the probe terminal and applying an input signal from the burn-in test apparatus to the input terminal. In the second method, the step a) includes the sub-steps of: a1) judging whether the integrated circuit provided on the semiconductor chip is good or not by the self-test circuit; and a2) stopping, when the integrated circuit is judged to be defective in the step a1), the burin-in test to the semiconductor chip and continuing, when the integrated circuit is judged to be good in the step a1), the burn-in test to the semiconductor chip.

According to this method, the burn-in test for detective chips can be stopped, so that needless power supply to a defective chip can be reduced. Moreover, a flow of a large current in a defective chip while a burn-in test is preformed can be prevented, so that a test can be performed more accurately and breakdown of the burn-in test apparatus can be prevented.

A third method for testing a semiconductor integrated circuit device according to the present invention is a method for testing a semiconductor integrated circuit device, in which a burn-in test of an integrated circuit provided on a semiconductor chip formed in a wafer and including a self-test circuit and a FAIL number count circuit is performed using a burn-in test apparatus and a probe card in which a probe terminal is provided and which is to be connected to the burn-in test apparatus when a test is performed. The method includes the step of a) performing a burn-in test of electric characteristics of the integrated circuit in a wafer level by connecting an input terminal on the semiconductor chip and the probe terminal and applying an input signal from the burn-in test apparatus to the input terminal. In the third method, the step a) includes the sub-steps of: a1) judging whether the integrated circuit provided on the semiconductor chip is good or not by the self-test circuit; a2) counting the number of times the semiconductor chip is judged to be defective in the sub-step a1) and judging, when a count value is equal to or lower than a predetermined value, the semiconductor chip to be good and, when the count value is larger than the predetermined value, to be defective; and a3) stopping the burn-in test to the semiconductor chip when the semiconductor chip is judged to be defective in the sub-step of a2).

According to this method, when noise is imposed on an input signal and the like, misjudgment of judging an originally good chip is judged to be defective can be prevented.

A fourth method for testing a semiconductor integrated circuit device according to the present invention is a method for testing a semiconductor integrated circuit device, in which a burn-in test of an integrated circuit provided on a semiconductor chip formed in a wafer and including a first self-test circuit, a second self-test circuit and a judging circuit is performed using a burn-in test apparatus and a probe card in which a probe terminal is provided and which is to be connected to the burn-in test apparatus when a test is performed. The method includes the step of a) performing a burn-in test of electric characteristics of the integrated circuit in a wafer level by connecting an input terminal on the semiconductor chip and the probe terminal and applying an input signal from the burn-in test apparatus to the input terminal. In the fourth method, the step a) includes the sub-steps of: a1) judging whether the integrated circuit provided on the semiconductor chip is good or not by the first self-test circuit; a2) judging, when the semiconductor chip is judged to be defective in the sub-step a1), whether the semiconductor chip is good or not by the second self-test circuit; a3) judging, when a judgment result indicates defective in each of the sub-step a1) and the sub-step a2), the semiconductor chip to be defective by the judging circuit; and a4) stopping the burn-in test to the semiconductor chip when the semiconductor chip is judged to be defective in the sub-step of a3).

According to this method, misjudgment of judging an originally good chip to be defective for an expected reason such as noise can be prevented.

A fifth method for testing a semiconductor integrated circuit device according to the present invention is a method for testing a semiconductor integrated circuit device, in which using a burn-in test apparatus, a probe card in which a probe terminal is provided and which is to be connected to the burn-in test apparatus when a test is performed and an off-chip circuit provided for each semiconductor chip formed in a wafer so as to be located on an associated one of scribe lines of the wafer, a burn-in test of an integrated circuit provided on a semiconductor chip is performed. The method comprising the step of a) performing a burn-in test of electric characteristics of the integrated circuit in a wafer level by connecting an input terminal on the semiconductor chip and the probe terminal and applying an input signal from the burn-in test apparatus to the input terminal. In the fifth method, the step a) includes the sub-steps of: a1) judging, in response to a control signal from the semiconductor chip, whether the integrated circuit provided on the semiconductor chip is good or not by the off-chip circuit; and a2) stopping by the off-chip circuit the burn-in test to the semiconductor chip when the semiconductor chip is judged to be defective in the sub-step of a1).

Thus, even when a circuit (off-chip circuit) for stopping, based on a control signal output from a semiconductor chip, a burn-in test is provided outside the semiconductor chip, power supply to a defective chip can be stopped and surplus power supply can be reduced. Moreover, a flow of a large current in a defective chip can be prevented and drop of a voltage to be supplied to a good chip can be suppressed. Accordingly, an accurate test can be performed.

A semiconductor integrated circuit device according to the present invention is a semiconductor integrated circuit device which includes an input terminal for receiving an input signal and is provided on a semiconductor chip. The semiconductor integrated circuit device has the function of performing, when a burn-in test for testing the semiconductor integrated circuit device is performed, a self-test on whether the semiconductor chip on which the semiconductor integrated circuit device itself is provided is good or not according to an input of the input signal to the input terminal and stopping, when the semiconductor chip is judged to be defective, the burn-in test.

With this structure, a flow of a large current in a defective chip when a burn-in test is performed can be prevented and an accurate test can be performed.

A first wafer according to the present invention is a semiconductor wafer in which a plurality of semiconductor chips are provided, each of the semiconductor chips including an input terminal for receiving an input from the outside, an output terminal for outputting a self-test result when the burn-in test is performed, and an integrated circuit. In the wafer, each of the plurality of semiconductor chips has the function of stopping, when judging itself to be defective in the self-test while the burn-in test is performed, the burn-in test.

With this structure, when wafer level burn-in is performed, a test is not performed for a defective chip. Thus, a flow of a large current in a defective chip can be prevented.

A burn-in apparatus according to the present invention is a burn-in test apparatus for testing a plurality of semiconductor chips formed in a semiconductor wafer by outputting a test signal and receiving a PASS signal or a FAIL signal according to the test signal. The apparatus includes observation means for recording how many times and at what time the FAIL signal is received in a test.

Thus, a convergence of initial failure occurrence in burn-in test steps can be accurately understood. Accordingly, an optical burn-in time can be set and a needless burn-in time can be eliminated, so that a burn-in test can be effectively performed.

### EFFECTS OF THE INVENTION

According to the present invention, a defective chip which becomes a problem in a burn-in test can be reliably eliminated from a test target. Accordingly, adverse influences of defective chips on good chips can be reduced. Moreover, unnecessary power supply can be reduced by stopping an operation of a defective chip generated while a burn-in test is performed or power supply to a defective chip.

Moreover, a convergence of initial failure occurrence in burn-in test steps can be accurately understood by recording a FAIL time and the number of defective chips generated while a burn-in test is performed. Accordingly, an optical burn-in time can be set and a needless burn-in time can be eliminated, so that a burn-in test can be effectively performed. An input terminal is shared by multiple components on a wafer and a signal line is shared due to application of an output signal of one chip to an input signal of another chip, so that signal application becomes possible with a small number of probes. With a self-test circuit which can perform a shipment level test provided, a test is performed in parallel while a burn-in test is performed, so that a burn-in test time can be effectively used. This largely contributes reduction in,entire test costs.

### BRIEF DESCRIPTION OF THE DRAWINGS

FIG. 1 is a flowchart illustrating respective steps for fabricating a semiconductor integrated circuit according to a first embodiment of the present invention and testing the semiconductor integrated circuit.

FIG. 2 is a block diagram illustrating a semiconductor integrated circuit device according to a second embodiment of the present invention.

FIG. 3 is a block diagram illustrating a first modified example of the semiconductor integrated circuit device of the second embodiment.

FIG. 4 is a block diagram illustrating a semiconductor integrated circuit device according to a second modified example of the second embodiment.

FIGS. 5(a) and 5(b) are diagrams illustrating a semiconductor integrated circuit device according to a third embodiment of the present invention when a burn-in test is performed.

FIG. 6 is a diagram illustrating a semiconductor integrated circuit device according to a fourth embodiment of the present invention.

FIG. 7 is a diagram illustrating a semiconductor integrated circuit device according to a fifth embodiment of the present invention.

FIG. 8 is a diagram illustrating a semiconductor integrated circuit device according to a sixth embodiment of the present invention.

FIG. 9 is a diagram illustrating a semiconductor integrated circuit device according to a seventh embodiment of the present invention.

FIG. 10 is a diagram illustrating a semiconductor integrated circuit device according to an eighth embodiment of the present invention.

FIG. 11 is a flowchart showing a known method for testing a semiconductor integrated circuit.

### EXPLANATION OF REFERENCE NUMERALS

3a, 11a Input signal

3b, 4a, 5a, 5b, 6a, 7b Judgment signal

3c Input data signal

7a Control signal

9a Stop signal

10a Signal line

11 Fabrication process step

11b Output signal

12 Probe test

13 Test result calculation

14 Protective film forming step for good chip

15 Protective film forming step for defective chip

16 Wafer level burn-in

31 Semiconductor chip

32 Burn-in test apparatus

33 First self-test circuit

34 Clock generation circuit

35 Input signal control circuit

36, 74, 101, 111 Input terminal

41 FAIL number count circuit

51 Second self-test circuit

52 Judging circuit

61 Semiconductor wafer

62 Probe terminal

63 Power supply line

64, 73, 112 Output terminal

65 Power supply control means

71 Scribe line

72 Off-chip circuit

81 Observation means

102 Burn-in test terminal

### BEST MODE FOR CARRYING OUT THE INVENTION

Hereafter, embodiments of the present invention will be described with reference to the accompanying drawings.

### First Embodiment

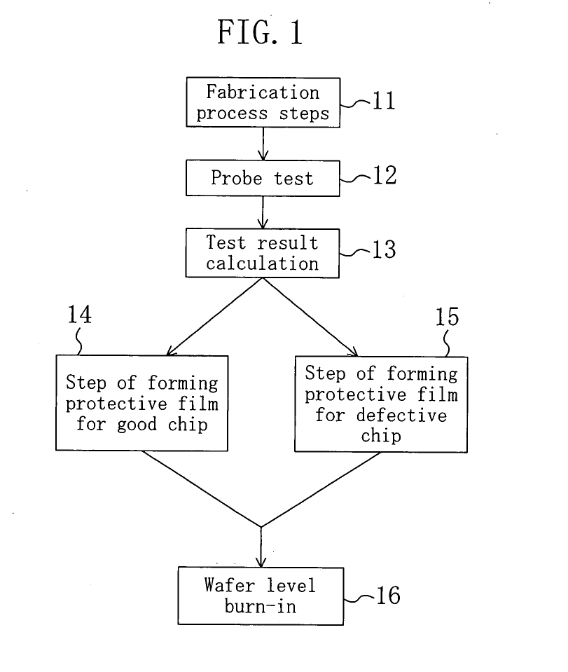

FIG. 1 is a flowchart illustrating respective steps for fabricating a semiconductor integrated circuit according to a first embodiment of the present invention and testing the semiconductor integrated circuit. FIG. 1 illustrates steps from a step of diffusion and interconnecting for semiconductor chip to a wafer level burn-in step.

In a method for fabricating and testing a semiconductor integrated circuit according to this embodiment, a semiconductor chip fabrication process step 11 including a diffusion step, an interconnecting step and the like is performed. Next, a probe test 12 for a semiconductor chip formed in the previous step is performed. Thereafter, results of the probe test 12 are calculated (test result calculation 13). According to a calculation result, for a semiconductor chip judged to be good, the process proceeds to a step of forming a first protective film (protective film forming step 14 for a good chip) and, on the other hand, for a semiconductor chip judged to be defective, the process proceeds a step of forming a second protective film (protective film forming step 15 for a defective chip). Next, wafer level burn-in 16 is performed.

The foregoing steps will be described in more detail.

After completion of the semiconductor chip fabrication process step 11, the probe test 12 is performed. The probe test 12 may be performed to judge whether or not wafer level burn-in can be performed, or may be performed in accordance with items determined by corporate standards and the like.

Subsequently, the test result calculation 13 is performed and coordinates indicating a nondefective(s) and a defective(s) on a wafer map are stored in an external apparatus such as a prove test apparatus.

Next, a first mask to be used in the protective film forming step 14 for a good chip and a second mask to be used in the protective film forming step 15 for a defective chip are prepared. The first mask is a mask for a chip judged to be good by the probe test 12 and includes holes in an electrode pad portion. The second mask is a mask for a chip judged to be defective by the probe test 12 and does not include holes in a pad portion. That is, the first mask is a mask through which a power supply and an input waveform can be applied when wafer level burn-in is performed, and the second mask is a mask through which a power supply and an input waveform can not be applied when wafer level burn-in is performed. The second mask gives insulation to the chip.

Then, in a protection film exposure apparatus, according to information stored in the test result calculation 13, the first mask for forming the first protective film is formed on a chip having coordinates of nondefective in the wafer map and the second mask for forming the second protective film is formed on a chip having coordinates of defective. Specifically, different masks are used for a good chip and a defective chip, respectively, on a single wafer so that wafer level burn-in is performed to the good chip but not to the defective chip at this stage. Depending on an exposure pattern, two different masks do not have to be prepared but only a signal mask for a good chip has to be prepared. That is, there might be cases where a protective film can be formed all over the chip without a mask. Thus, an entire surface of a defective chip can be made nonconductive.

As has been described, by preparing two different protective film masks and performing semiconductor diffusion process to a good chip and a defective chip using the different protective masks, respectively, a power supply terminal, a GND terminal and an input/output terminal of the defective chip is made nonconductive by an insulating surface protective film (second mask). As a result, in a burn-in test step, power supply and signal application to a defective chip can be reliably cut off, so that a flow of a large current having a current value equal to or larger than a predetermined level in a good chip can be prevented.

According to a known method, there are cases where coating failure occurs or exfoliation of resin occurs. However, in the method of this embodiment, a protective film is formed in normal semiconductor diffusion process, so that there are even fewer chances of failure of mask formation, compared to the known method.

The step of forming a protective film using a mask for a good chip is also a step in which known semiconductor diffusion process is performed. Accordingly, even when the flow of FIG. 1 is executed, an additional step or an additional apparatus is not required. Therefore, according to the method of this embodiment, without increasing fabrication costs, breakdown of a good chip in a test can be prevented and a yield can be increased.

### Second Embodiment

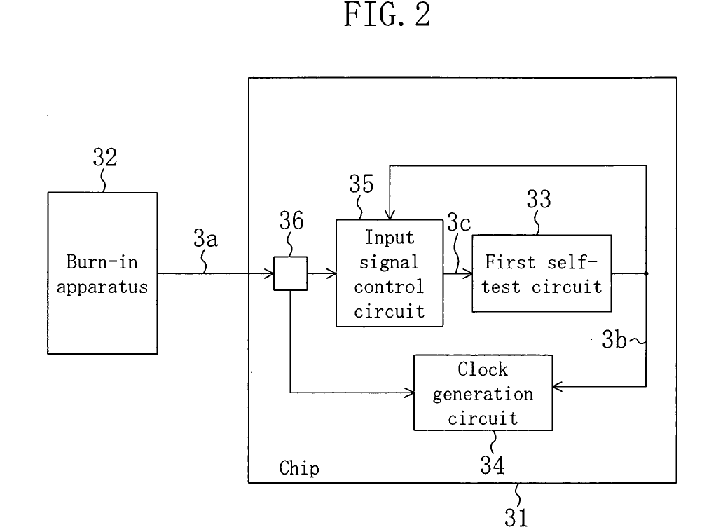

FIG. 2 is a block diagram illustrating a semiconductor integrated circuit device according to a second embodiment of the present invention. FIG. 2 illustrates a flow of a signal when wafer level burn-in is performed using a burn-in test apparatus.

As shown in FIG. 2, the semiconductor integrated circuit device (semiconductor chip 31) of this embodiment includes an input terminal 36 for receiving an input signal 3a output from a burn-in test apparatus 32, an input signal control circuit 35 for receiving the input signal 3a via an input terminal 36 and outputting an input data signal 3c in a predetermined case, a first self-test circuit 33 for starting an operation in response to an input of the input signal 3a and judging whether the semiconductor chip 31 is good or not, and a clock generation circuit 34 for generating a clock signal. In this case, the semiconductor chip 31 is a semiconductor integrated circuit on each of a plurality of chip regions formed in a wafer. However, the semiconductor chip 31 may be a packaged semiconductor integrated circuit device.

When a burn-in test is performed, the input signal 3a output by the burn-in test apparatus 32 is received by the input terminal 36 of the semiconductor chip 31. The input signal 3a may be a clock signal or a data signal. Receiving the input signal 3a, the semiconductor chip 31 starts an operation and the first self-test circuit 33 starts an operation. Then, the first self-test circuit 33 judges whether the semiconductor chip 31 is good or not and outputs a judgment result as a judgment signal 3b. The judgment signal 3b is received by the clock generation circuit 34 and the input signal control circuit 35. When the judgment signal 3b indicates a good judgment, the burn-in test is continuously performed. In contrast, when the judgment signal 3b indicates a defective judgment (FAIL signal), the clock generation circuit 34 is controlled to stop clock generation. Accordingly, after the control, a clock is not supplied into the semiconductor chip 31 which has been judged to be defective by the first self-test circuit 33. When the judgment signal 3b indicates a defective judgment, the input signal control circuit 35 is controlled so that the input data signal 3c is fixed. Accordingly, after the control, the input data signal 3c is fixed and a data signal is not received by the semiconductor chip 31 which has been judged to be defective by the first self-test circuit 33.

As has been described, the first self-test circuit 33 is provided in a chip and supply of an input signal and a clock signal to the chip is stopped according to a judgment signal of the first self-test circuit 33. Thus, an operation of a defective chip while a burn-in test is performed can be stopped, so that unnecessary power supply to the defective chip can be reduced. Moreover, a flow of a large current in a defective chip while a burn-in test is performed can be prevented. Therefore, a test can be accurately performed and breakdown of a burn-in test apparatus can be avoided.

Next, a modified example of the semiconductor integrated circuit device of this embodiment will be described.

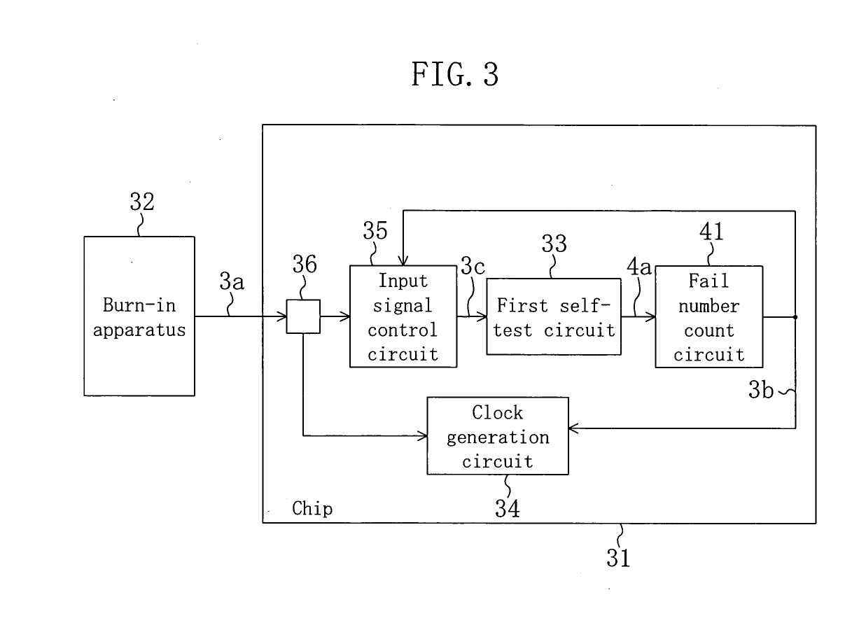

FIG. 3 is a block diagram illustrating a first modified example of the semiconductor integrated circuit device of this embodiment. As shown in FIG. 3, a semiconductor integrated circuit device according to the first modified embodiment is obtained by providing a FAIL number count circuit 41 in the semiconductor integrated circuit device of FIG. 2.

In the semiconductor integrated circuit device of this modified example, the FAIL number count circuit 41 receives a judgment signal 4a output from the first self-test circuit 33. The FAIL number count circuit 41 counts the number of times the FAIL number count circuit 41 has received the judgment signal 4a. When a count number is equal to or lower than a certain number of times, the semiconductor chip 31 is judged to be good, and when the count number is over the certain number of times, the semiconductor chip 31 is judged to be defective and a judgment result is output as the judgment signal 3b. As in the semiconductor integrated circuit device of the second embodiment, the judgment signal 3b is received by the clock generation circuit 34 and the input signal control circuit 35 and when the judgment signal 3b indicates a good judgment (PASS signal), the burn-in test is continuously performed. When the judgment signal 3b indicates a defective judgment (FAIL signal), the clock generation circuit 34 is controlled to stop clock generation. Accordingly, after the control, a clock is not supplied into the semiconductor chip 31 which has been judged to be defective by the first self-test circuit 33. When the judgment signal 3b indicates a defective judgment, the input signal control circuit 35 is controlled to fix the input data signal 3c. Accordingly, after the control, in the semiconductor chip 31 which has been judged to be defective by the first self-test circuit 33, the input data signal 3c is fixed and a data signal is not received by the chip.

As described above, the FAIL number count circuit 41 of FIG. 3 is provided. Thus, for example, when noise is imposed on the input signal 3a supplied by the burn-in test apparatus 32 and the semiconductor chip 31 and the semiconductor chip 31 is misoperated, misjudgment of judging an originally good chip to be defective can be prevented. That is, with use of the semiconductor integrated circuit device of this modified example, a burn-in test can be more accurately performed.

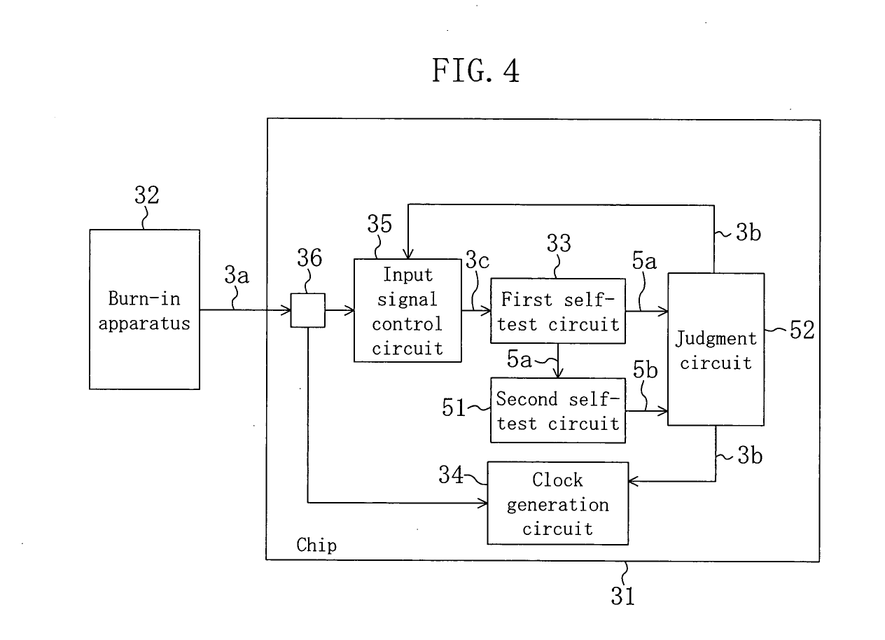

Next, FIG. 4 is a block diagram illustrating a semiconductor integrated circuit device according to a second modified example of this embodiment. A semiconductor integrated circuit according to this embodiment is obtained by providing a second self-test circuit 51 in the semiconductor integrated circuit device of FIG. 2.

As the first self-test circuit 33, the second self-test circuit 51 has the function of judging whether a chip is good or not but, when a chip is a good chip, the second self-test circuit 51 does not perform an operation.

In the semiconductor integrated circuit device of this modified example, the second self-test circuit 51 and a judging circuit 52 receive a judgment signal 5a output from the first self-test circuit 33. When the judgment signal 5a indicates a good judgment, as the second semiconductor integrated circuit device, the judging circuit 52 outputs the judgment signal 3b to each of the clock generation circuit 34 and the input signal control circuit 35 and the burn-in test is continuously performed. In this case, the second self-test circuit 51 is not operated and does not output a judgment result. In contrast, when the judgment signal 5a indicates a good judgment, the second self-test circuit 51 starts an operation and outputs a judgment signal 5b indicating whether a chip is good or not to the judging circuit 52. Even when the judgment signal 5a indicates a defective judgment, as long as the judgment signal 5b indicates a good judgment, the judging circuit 52 judges the semiconductor chip 31 to be good and outputs the judgment signal 3b. In contrast, when each of the judgment signals 5a and 5b indicates a defective judgment, the judging circuit 52 judges the semiconductor chip 31 to be defective and outputs the judgment signal 3b. As the semiconductor integrated circuit device of the second embodiment, the clock generation circuit 34 and the input signal control circuit 35 receive the judgment signal 3b and when the judgment signal 3b indicates a good judgment, the burn-in test is continuously performed. On the other hand, when the judgment signal 3b indicates a defective judgment (FAIL signal), the clock generation circuit 34 is controlled to stop clock generation. Accordingly, after the control, a clock is not supplied into the semiconductor chip 31 which has been judged to be defective by the judging circuit 52. When the judgment signal 3b indicates a defective judgment, the input signal control circuit 35 is controlled to fix the input data signal 3c. Thus, after the control, in the semiconductor chip 31 which has been judged to be defective by the judging circuit 52, the input data signal 3c is fixed and a data signal is not received by the chip.

As described above, a plurality of self-judging circuits are provided and, as shown in FIG. 3, when the semiconductor chip 31 is misoperated, another self-test circuit is operated. Thus, misjudgment of judging an originally good chip to be defective can be prevented. Note that even when the same self-test circuit is operated, misjudgment based on a misoperation can be also prevented.

A test method using the semiconductor integrated circuit device of this embodiment and a modified example of this embodiment can be performed in the same manner, even when a self-test circuit, a judging circuit, a FAIL number count circuit and the like are provided outside of a semiconductor chip, e.g., on a scribe line of a chip.

### Third Embodiment

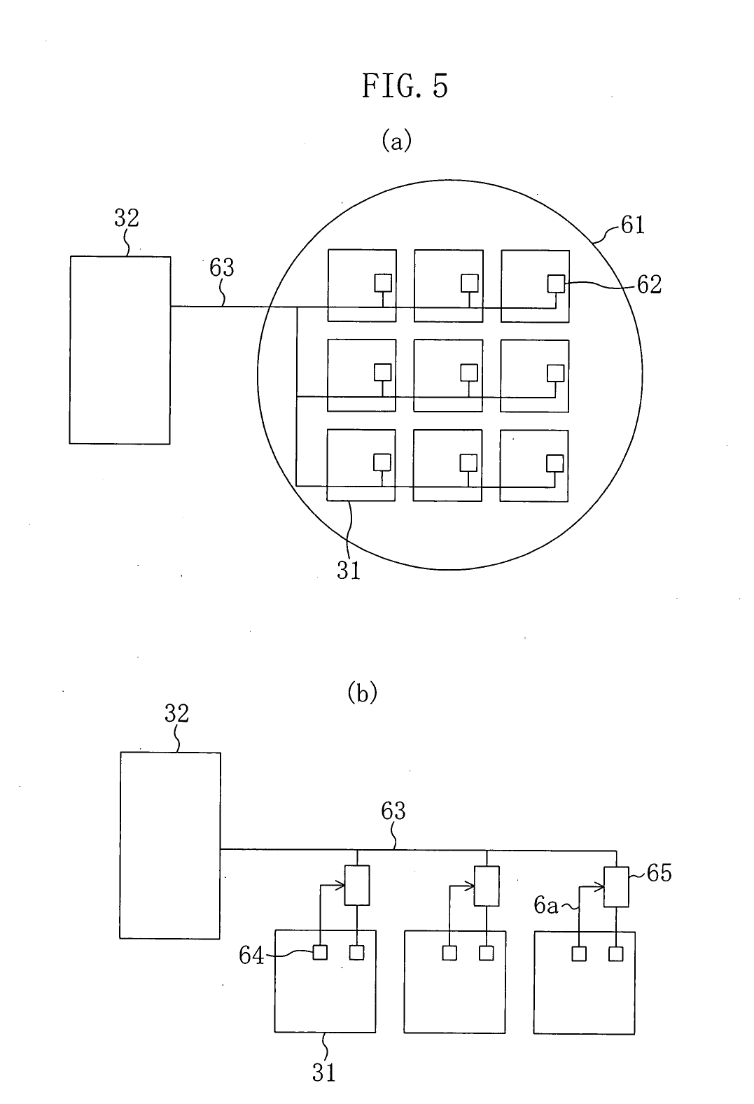

FIGS. 5(a) and 5(b) are diagrams illustrating a semiconductor integrated circuit device according to a third embodiment of the present invention when a burn-in test is performed. FIG. 5(b) is an enlarged view of FIG. 5(a).

When a burn-in test is performed, an input terminal 36 (see FIG. 2) of each of a plurality of semiconductor chips 31 and an associated one of probe terminals 62 of a probe card are kept connected with each other and power is applied from a burn-in test apparatus 32 to the probe card via a power supply line 63. On the power supply line 63 provided on the probe card, power supply control means 65 is provided and controls whether or not to supply power to the semiconductor chip 31. The semiconductor chip 31 is, for example, a semiconductor integrated circuit device of the second embodiment and outputs, as a judgment signal 6a, a judgment signal 3b of the semiconductor chip 31 from an output terminal 64 to the power supply control means 65. When the judgment signal 6a indicates a good judgment, power is continuously supplied to the semiconductor chip 31 by the power supply control means 65 and the burn-in test is continuously performed. When the judgment signal 6a indicates a defective judgment, power supply to the semiconductor chip 31 is stopped by the power supply control means 65 and the burn-in test for the semiconductor chip 31 is terminated.

The power supply control means 65 is capable of measuring a value of a current flowing in a chip and has the function of stopping power supply when a current having a current value equal to or larger than a certain level flows. Even if the judgment signal 6a indicates a good judgment, with a current having a larger value than the predetermined value flowing in the semiconductor chip 31, power supply to the semiconductor chip 31 is stopped.

As described above, power supply to each of a good chip and a defective chip is controlled using the power supply control means 65, so that a large current flowing in a defective chip can be cut off. Moreover, when a value of a current flowing in the semiconductor chip 31 is measured and a chip in which a current equal to or larger than a certain level is judged to be defective, a burn-in test for the chip is stopped. Thus, a chip which does not fill power dissipation of the semiconductor chip 31 can be judged to be defective. With the above-described method, adverse effects on a good chip can be reduced and a stable burn-in test can be preformed.

The test method of this embodiment is applicable not only to the semiconductor integrated circuit device of the second embodiment but also to modified examples of the second thereof.

### Fourth Embodiment

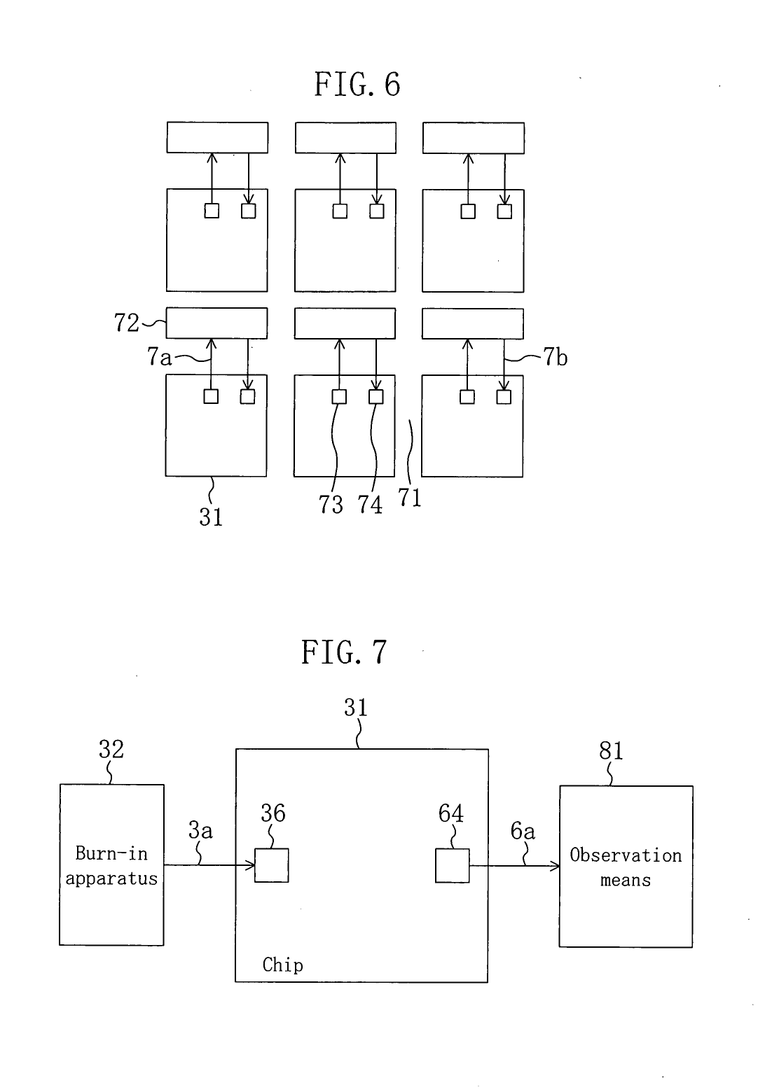

FIG. 6 is a diagram illustrating a semiconductor integrated circuit device according to a fourth embodiment of the present invention.

As shown in FIG. 6, the semiconductor integrated circuit device of this embodiment includes a plurality of semiconductor chips 31 formed in a semiconductor wafer 61 and off-chip circuits 72 formed on scribe lines 71 of the semiconductor wafer 61. When a burn-in test is performed, each of the chips is connected to a burn-in test apparatus via a probe card and a power supply and an input signal are supplied from the burn-in test apparatus to each of the chips.

Each of the off-chip circuits 72 is connected to an output terminal 73 and an input terminal 74 of an associated one of the semiconductor chips 31 and sends/receives a control signal 7a and a judgment signal 7b via those terminals, respectively. Each of the off-chip circuits 72 has the function of testing whether or not an associated one of the semiconductor chips 31 is good. Thus, each of the off-chip circuits 72 receives the control signal 7a output from an associated one of the semiconductor chips 31 to start testing and sends, as a judgment signal 7b, a judgment result on whether good or not to the associated one of the semiconductor chips 31. The associated one of the semiconductor chips 31 performs the processing described in the second embodiment according to the judgment result. That is, when the judgment signal 7b indicates a good judgment, the burn-in test is continuously performed. When the judgment signal 7b indicates a defective judgment (FAIL signal), a clock generation circuit is controlled to stop clock generation.

Accordingly, after the operation, a clock is not supplied into one(s) of the semiconductor chips 31 judged to be defective by the off-chip circuits 72. When the judgment signal 7b indicates a defective judgment, an input signal control circuit 35 is controlled to fix an input data signal. Thus, after the control, one(s) of the semiconductor chips 31 judged to be defective by the off-chip circuits 72 is fixed and a data signal is not received by the one(s) of the semiconductor chips 31.

As has been described, off-chip circuits each having the testing function are provided in external spaces (scribe lines) and, when a judgment signal of any one of the off-chip circuits indicates that a chip is defective, supply of an input signal and a clock signal into the chip is stopped. Thus, an operation of the defective chip while a burn-in test is performed can be stopped. By stopping power supply to a defective chip, a surplus power supply can be cut off and costs for a burn-in test can be reduced. Moreover, when a burn-in test is performed, reduction in voltage supplied to each chip can be suppressed and an accurate test can be performed.

The semiconductor integrated circuit device of this embodiment is not limited to use in a burn-in test performed to chips on a wafer, but may be applied to a case where a burn-in test is performed to chips as a whole in a package.

### Fifth Embodiment

FIG. 7 is a diagram illustrating a semiconductor integrated circuit device according to a fifth embodiment of the present invention.

When a burn-in test is performed to the semiconductor integrated circuit device of this embodiment, the input signal 3a is supplied from a burn-in test apparatus 32 via an input terminal 36 of a semiconductor chip 31. In this case, the burn-in test apparatus 32 outputs a test signal (input signal 3a) to the semiconductor chip 31 via a probe terminal and performs a burn-in test in response to a judgment signal output from an output terminal 64 of each semiconductor chip 31.

The semiconductor chip 31 is, for example, a semiconductor integrated circuit device of the second embodiment including a self-test circuit and has the function of judging whether the semiconductor chip 31 is good or not. The semiconductor chip 31 outputs, as a judgment signal 6a, a judgment result indicating whether good or not from an output terminal 64 to observation means 81. The observation means 81 can record how many times a FAIL signal has been received from the semiconductor chip 31 at what time point and which chip has output a FAIL signal. The observation means 81 may be provided in an off-wafer area. For example, the observation means 81 may be performed in the burn-in test apparatus 32 or in another apparatus located outside of the wafer.

A defective chip which outputs many FAIL signals, an unstable chip which outputs both of a PASS signal and a FAIL signal and the like are judged to be defective chips and are not sent to the next process step.

As described above, the observation means 81 for recording the number of defective chips generated while a burn-in test is performed and a FAIL time at which each of the defective chip is generated is provided, so that a convergence of initial failure occurrence in burn-in test steps can be accurately understood. Accordingly, an optical burn-in time can be set and a needless burn-in time can be eliminated, so that a burn-in test can be effectively performed.

### Sixth Embodiment

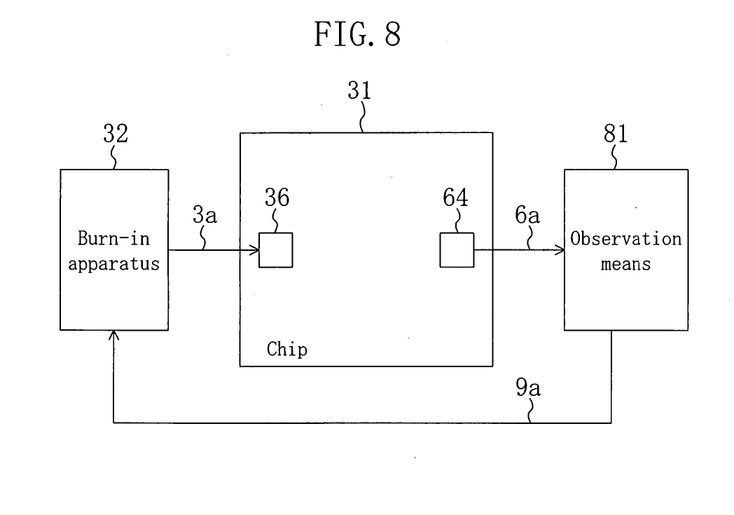

FIG. 8 is a diagram illustrating a semiconductor integrated circuit device according to a sixth embodiment of the present invention.

The semiconductor integrated circuit device of this embodiment is formed so that the observation means 81 outputs a stop signal 9a and the burn-in test apparatus 32 receives the stop signal 9a in the configuration of the semiconductor integrated circuit device of the fifth embodiment of FIG. 7. Specifically, the observation means 81 has not only the function of recording the number of times a FAIL signal has been received, a FAIL time at which the FAIL signal has been received and which chip has output the FAIL signal, which has been described in the fifth embodiment, but also has the instruction function of stopping application of a power supply and a signal. The observation means 81 may be configured so as to output an instruction to stop application of a power supply and a signal as soon as the observation means 81 receives a FAIL signal from a chip or output an instruction to stop application of a power supply and a signal when the number of the times a FAIL signal has been received reaches a predetermined value.

This embodiment may be configured as a method for sending a stop signal to the burn-in test apparatus 32 so that the stop signal 9a is output not via the observation means 81 but directly from the semiconductor chip 31 to the burn-in test apparatus 32.

Thus, surplus power supply to a defective chip can be cut off and costs for a burn-in test can be reduced.

### Seventh Embodiment

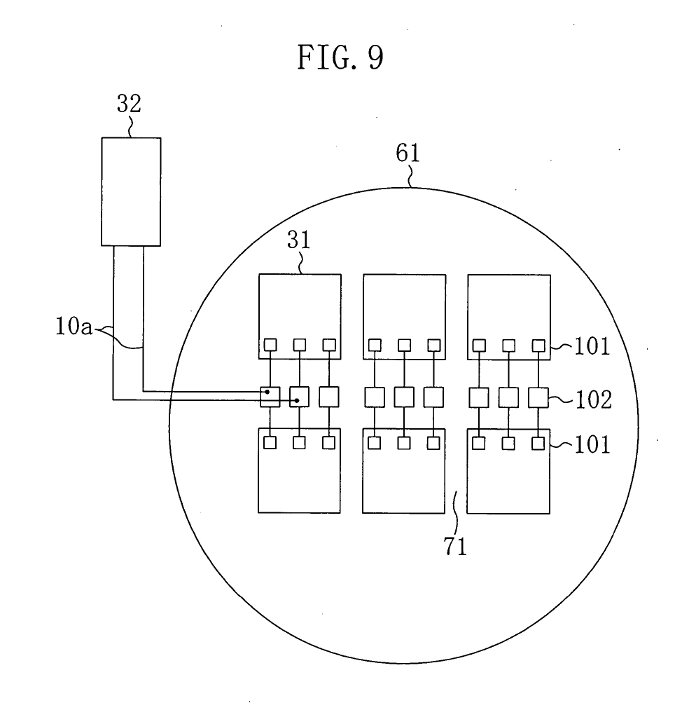

FIG. 9 is a diagram illustrating a semiconductor integrated circuit device according to a seventh embodiment of the present invention.

A semiconductor wafer 61 on which the semiconductor integrated circuit device of this embodiment is provided includes a plurality of semiconductor chips 31 having input terminals 101, respectively, and burn-in test terminals 102 formed on scribe lines 71 and the like so that each of the burn-in test terminal 102 is connected to an associated one of the input terminals 101.

When a burn-in test is performed, each of the input terminals 101 and an associated one of the burn-in test terminals 102 are electrically connected to each other via a signal line 10a. A single one of the burn-in test terminals 102 may be connected to plural ones of the input terminals 101. With the burn-in test terminals 102 connected to probe terminals 62 (see FIG. 5(a)) of a probe card, respectively, the input signal 3a is applied to the probe card from a burn-in test apparatus 32. The signal line 10a does not have to be provided on a surface of the semiconductor wafer 61 but may be provided inside of the wafer. Moreover, in a test performed on a wafer before a burn-in test, for a chip judged to be defective, the signal line 10a is cut off by laser in advance, so that supply of power and a signal can be cut off. The burn-in test terminals 102 and signal line 10a are cut and separated in a dicing step. Therefore, input terminals of the semiconductor chips 31 are not particularly affected.

As has been described, terminals for a burn-in test are provided in empty spaces such as a scribe line on a wafer so that an input signal is shared. Thus, signal application to each semiconductor chip with a small number of probe terminals becomes possible. Moreover, by separately providing terminals for a burn-in test, damages of terminals due to connection between terminals when a burn-in test is performed can be prevented.

### Eighth Embodiment

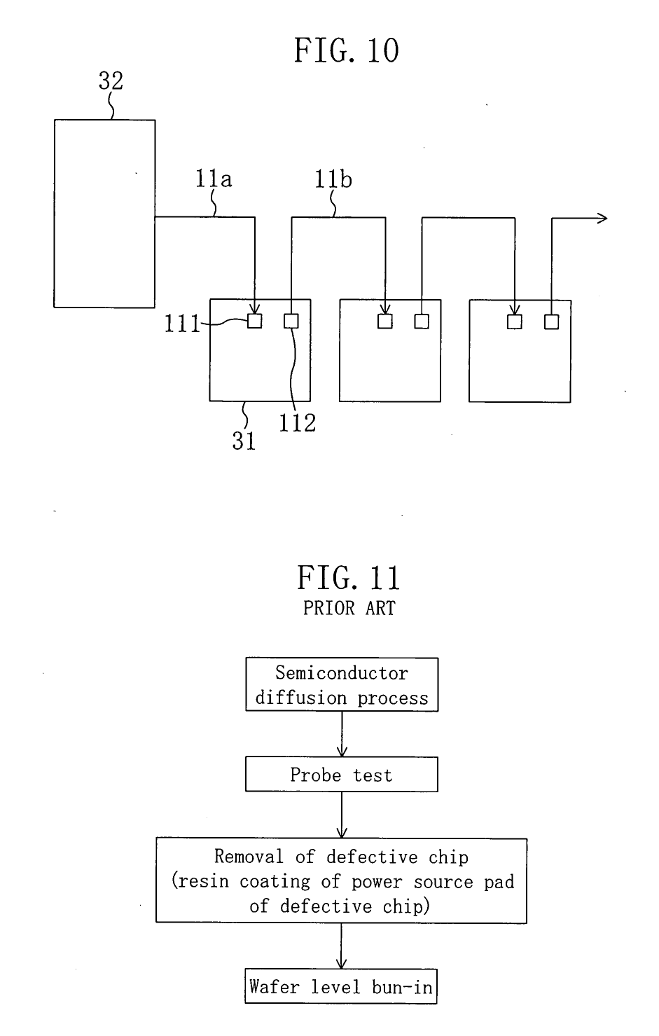

FIG. 10 is a diagram illustrating a semiconductor integrated circuit device according to an eighth embodiment of the present invention.

As shown in FIG. 10, a plurality of semiconductor chips 31 each having an input terminal 111 and an output terminal 112 are provided on a semiconductor wafer of this embodiment. Each of the semiconductor chips 31 may be a semiconductor integrated circuit device in a form of chip formed in a wafer or may be a packaged semiconductor integrated circuit device.

In a burn-in test, when one of the semiconductor chips 31 receives an input signal 11a output from a burn-in test apparatus 32 at an associated one of the input terminal 111, an output signal 11b is output from the output terminal 112. An output terminal 112 of each of the semiconductor chips 31 is connected to an input terminal 111 of its adjacent one of the semiconductor chips 31 which has an output terminal 112 connected to an input terminal 111 of a next one to the adjacent one of the semiconductor chips 31. For example, when the semiconductor chips 31 perform a SCAN operation, input terminals 111 serve as SCAN IN terminals and output terminals 112 serve as SCAN OUT terminals. Thus, a plurality of chips can be tested at a time by a single signal line. The input terminals 111 and the output terminals 112 of the semiconductor chips 31 for transmission of an input signal 11a and an output signal 11b are electrically connected to one another.

As has been described, an output signal of a chip is applied as an input signal to another chip. Thus, a signal can be supplied to a plurality of chips by a single line and a plurality of chips can be tested at a time. Accordingly, signal application to a plurality of chips with a small number of probe terminals becomes possible. Therefore, in the future, even if the number of semiconductor chips obtained from a wafer is increased due to reduction in the semiconductor diffusion process design and increase in a diameter of a wafer, a burn-in test can be performed without any problem using the semiconductor integrated circuit device of the present invention.

### INDUSTRIAL APPLICABILITY

A semiconductor integrated circuit device according to the present invention and a method for testing the semiconductor integrated circuit device are useful in wafer level burn-in for performing a burn-in test to a plurality of semiconductor integrated circuits formed on a single wafer at a time.

1. A method for testing a semiconductor integrated circuit device, the method comprising the steps of:
a) testing whether a semiconductor chip formed in a wafer is good or not in a wafer state, the semiconductor chip including an integrated circuit having an electrode pad;
b) forming a first insulative mask on part of the semiconductor chip other than the electrode pad when it has been judged as to be good in the step a);
c) forming a second insulative mask on an entire upper surface of the semiconductor chip when it has been judged to be defective in the step a); and
d) performing a burn-in test of the wafer using a burn-in test apparatus.

2. A method for testing a semiconductor integrated circuit device, in which a burn-in test of an integrated circuit provided on a semiconductor chip formed in a wafer and including a self-test circuit is performed using a burn-in test apparatus and a probe card in which a probe terminal is provided and which is to be connected to the burn-in test apparatus when a test is performed, the method comprising the step of a) performing a burn-in test of electric characteristics of the integrated circuit in a wafer level by connecting an input terminal on the semiconductor chip and the probe terminal and applying an input signal from the burn-in test apparatus to the input terminal,
wherein the step a) includes the sub-steps of:
a1) judging whether the integrated circuit provided on the semiconductor chip is good or not by the self-test circuit; and
a2) stopping, when the integrated circuit is judged to be defective in the step a1), the burn-in test to the semiconductor chip and continuing, when the integrated circuit is judged to be good in the step a), the burn-in test to the semiconductor chip.

3. The method of claim 2, wherein the self-test circuit is provided in the integrated circuit of the semiconductor chip.

4. The method of claim 2, wherein in the sub-step a2), when the semiconductor chip is judged to be defective in the sub-step a1), the burn-in test is stopped by stopping a clock in the integrated circuit or cutting off the input signal.

5. The method of claim 2, wherein in the burn-in test apparatus or the probe card, power supply control means for controlling a power supply source for supplying power to the semiconductor chip to be ON or OFF is provided,
in the sub-step a2), when the semiconductor chip is judged to be defective in the sub-step a1), the power supply control means stops, in response to an output signal from the semiconductor chip, an operation of the power supply source for supplying power to the semiconductor chip.

6. The method of claim 5, wherein the power supply control means has the function of monitoring an amount of a current flowing in the semiconductor chip and in the step a), when a current having a current value equal to or larger than a predetermined value flows in the semiconductor chip, the power supply control means stops power supply to the semiconductor chip.

7. A method for testing a semiconductor integrated circuit device, in which a burn-in test of an integrated circuit provided on a semiconductor chip formed in a wafer and including a self-test circuit and a FAIL number count circuit is performed using a burn-in test apparatus and a probe card in which a probe terminal is provided and which is to be connected to the burn-in test apparatus when a test is performed, the method comprising the step of a) performing a burn-in test of electric characteristics of the integrated circuit in a wafer level by connecting an input terminal on the semiconductor chip and the probe terminal and applying an input signal from the burn-in test apparatus to the input terminal,
wherein the step a) includes the sub-steps of:
a1) judging whether the integrated circuit provided on the semiconductor chip is good or not by the self-test circuit;
a2) counting the number of times the semiconductor chip is judged to be defective in the sub-step a1) and judging, when a count value is equal to or lower than a predetermined value, the semiconductor chip to be good and, when the count value is larger than the predetermined value, to be defective; and
a3) stopping the burn-in test to the semiconductor chip when the semiconductor chip is judged to be defective in the sub-step of a2).

8. A method for testing a semiconductor integrated circuit device, in which a burn-in test of an integrated circuit provided on a semiconductor chip formed in a wafer and including a first self-test circuit, a second self-test circuit and a judging circuit is performed using a burn-in test apparatus and a probe card in which a probe terminal is provided and which is to be connected to the burn-in test apparatus when a test is performed, the method comprising the step of a) performing a burn-in test of electric characteristics of the integrated circuit in a wafer level by connecting an input terminal on the semiconductor chip and the probe terminal and applying an input signal from the burn-in test apparatus to the input terminal,
wherein the step a) includes the sub-steps of:
a1) judging whether the integrated circuit provided on the semiconductor chip is good or not by the first self-test circuit;
a2) judging, when the semiconductor chip is judged to be defective in the sub-step a1), whether the semiconductor chip is good or not by the second self-test circuit;
a3) judging, when a judgment result indicates defective in each of the sub-step a1) and the sub-step a2), the semiconductor chip to be defective by the judging circuit; and
a4) stopping the burn-in test to the semiconductor chip when the semiconductor chip is judged to be defective in the sub-step of a3).

9. A method for testing a semiconductor integrated circuit device, in which using a burn-in test apparatus, a probe card in which a probe terminal is provided and which is to be connected to the burn-in test apparatus when a test is performed and an off-chip circuit provided for each semiconductor chip formed in a wafer so as to be located on an associated one of scribe lines of the wafer, a burn-in test of an integrated circuit provided on a semiconductor chip is performed, the method comprising the step of a) performing a burn-in test of electric characteristics of the integrated circuit in a wafer level by connecting an input terminal on the semiconductor chip and the probe terminal and applying an input signal from the burn-in test apparatus to the input terminal,
wherein the step a) includes the sub-steps of:
a1) judging, in response to a control signal from the semiconductor chip, whether the integrated circuit provided on the semiconductor chip is good or not by the off-chip circuit; and
a2) stopping by the off-chip circuit the burn-in test to the semiconductor chip when the semiconductor chip is judged to be defective in the sub-step of a1).

10. The method of claim 3, wherein observation means for receiving an output signal from the semiconductor chip is provided in the burn-in test apparatus or the probe card, and
the step a) further includes the sub-step of a5) recording, by the observation means, how many times and at what time the output signal indicating that the semiconductor chip is defective is output in the sub-step a1).

11. The method of claim 10, wherein the step a) further includes the sub-step of a6) making, by the observation means, the burn-in test apparatus stop supply of power and a signal to the semiconductor chip.

12. A semiconductor integrated circuit device which includes an input terminal for receiving an input signal and is provided on a semiconductor chip, the device comprising means for performing, when a burn-in test for testing the semiconductor integrated circuit device is performed, a self-test on whether the semiconductor chip on which the semiconductor integrated circuit device itself is provided is good or not according to an input of the input signal to the input terminal and stopping, when the semiconductor chip is judged to be defective, the burn-in test.

13. The semiconductor integrated circuit device of claim 12, further comprising a first self-test circuit for receiving the input signal which the input terminal has received and testing whether the semiconductor chip is good or not,
wherein the burn-in test is stopped using a test result of the first self-test circuit.

14. The semiconductor integrated circuit device of claim 13, further comprising an input signal control circuit which is provided between the input terminal and the first self-test circuit and to which the test result of the first self-test circuit is fed back,
wherein when the first self-test circuit judges that the semiconductor chip is defective, the input signal control circuit outputs a fixed input data signal to the first self-test circuit, thereby stopping the burn-in test.

15. The semiconductor integrated circuit device of claim 13, further comprising a clock generation circuit for receiving the test result of the first self-test circuit, the clock generation circuit being connected to the input terminal,
wherein when the first self-test circuit judges that the semiconductor chip is defective, the generation of a clock by the clock generation circuit is stopped, thereby stopping the burn-in test.

16. The semiconductor integrated circuit device of claim 13, further comprising a FAIL number count circuit for counting the number of times the semiconductor chip is judged to be defective by the first self-test circuit and judging, when a count value is equal to or lower than a predetermined value, the semiconductor chip to be good and, when the count value is larger than the predetermined value, to be defective and stopping the burn-in test.

17. The semiconductor integrated circuit device of claim 13, further comprising:
a second self-test circuit for further performing, when the first self-test circuit judges that the semiconductor chip is defective, a test of the semiconductor chip and, not performing its operation when the first self-test circuit judges that the semiconductor chip is good; and
a judging circuit for stopping, when the first self-test circuit and the second self-test circuit judge that the semiconductor chip is defective, the burn-in test.

18. The semiconductor integrated circuit device of claim 13, further comprising an output terminal for outputting a self-test result of the semiconductor chip.

19. A semiconductor wafer in which a plurality of semiconductor chips are provided, each of the semiconductor chips including an input terminal for receiving an input from the outside, an output terminal for outputting a self-test result when the burn-in test is performed, and an integrated circuit,
wherein each of the plurality of semiconductor chips has the function of stopping, when judging itself to be defective in the self-test while the burn-in test is performed, the burn-in test.

20. The semiconductor wafer of claim 19, wherein scribe lines are formed so that each of the scribe lines is provided between adjacent ones of the plurality of the semiconductor chips, and
the semiconductor wafer further includes off-chip circuits for outputting, when in response to the test result of the semiconductor chips, at least one of the semiconductor chips is judged to be defective, a judgment signal for stopping the burn-in test to said at least one of the semiconductor chips which has been judged to be defective, the off-chip circuits being formed so that each of the off-chip circuits is provided on an associated one of the scribe lines and per several ones of the semiconductor chips.

21. The semiconductor wafer of claim 19, further comprising test terminals provided outside of the plurality of the semiconductor chips so that each of the test terminals is connected to the input terminals of two or more of the semiconductor chips.

22. The semiconductor wafer of claim 19, wherein the plurality of semiconductor chips includes multiple semiconductor chips having output terminals connected to input terminals of their adjacent semiconductor chips, respectively, and
an input signal from the outside of the wafer which is to be received by the semiconductor chips is serial transmitted to the multiple ones of the plurality of semiconductor chips connected to one another.

23. A burn-in test apparatus for testing a plurality of semiconductor chips formed in a semiconductor wafer by outputting a test signal and receiving a PASS signal or a FAIL signal according to the test signal, the apparatus comprising observation means for recording how many times and at what time the FAIL signal is received in a test.

24. The burn-in test apparatus of claim 23, wherein when the observation means receives the FAIL signal, the observation means stops supply of power or the test signal to at least one of the semiconductor chips which has output the FAIL signal.

25. The burn-in test apparatus of claim 23, wherein when the number of times the FAIL signal is received reaches a predetermined value, the observation means stops supply of power or the test signal to at least one of the semiconductor chips which has output the FAIL signal.
